(19) United States
(12) Patent Application Publication
(10) Pub. No.: US 2024/0246454 A1
(43) Pub. Date: Jul. 25, 2024

(54) METHOD FOR ELECTRICALLY CHARGING A DRIVE BATTERY, COMPUTER PROGRAMME PRODUCT, AND STORAGE MEANS

(71) Applicant: Volkswagen Aktiengesellschaft, Wolfsburg (DE)

(72) Inventors: Jan-Christoph Albrecht, Wolfsburg (DE); Jochen Westhäuser, Braunschweig (DE)

(21) Appl. No.: 18/560,017

(22) PCT Filed: May 10, 2022
(86) PCT No.: PCT/EP2022/062650

§ 371 Date: Nov. 9, 2023

(30) Foreign Application Priority Data
May 11, 2021 (DE) 102021112242.2

(51) Int. Cl. B60L 58/26; B60L 53/66; H05K 7/20

(52) U.S. Cl. CPC B60L 58/26; B60L 53/66; H05K 7/20354; H05K 7/20909; H05K 7/20936; B60L 2270/142

(57) ABSTRACT

Technologies and techniques for electrically charging a drive battery for a vehicle at a charging station. The vehicle may include a refrigerant compressor for cooling the drive battery using a refrigerant; and a fan for cooling the refrigerant. A method may include the steps of cooling the drive battery using the refrigerant compressor during electric charging of the drive battery; and cooling the refrigerant using the fan during electric charging of the drive battery, wherein an upper charging noise level limit is provided and the operating mode of the refrigerant compressor and the operating mode of the fan are adjusted taking into consideration said upper charging noise level limit. A computer program product may be configured for carrying out a method according to the present disclosure.

### RELATED APPLICATIONS

The present application claims priority to International Patent Application No. PCT/EP2022/062650 to Albrecht, et al., filed May 10, 2022, titled “Method for Electrically Charging a Drive Battery, Computer Programme Product, and Storage Means,” which claims priority to German Pat. App. No. DE 10 2021 112 242.2 filed May 11, 2021, to Albrecht, et al., the contents of each being incorporated by reference in their entirety herein.

### TECHNICAL FIELD

The present disclosure relates to technologies and techniques for electrically charging a drive battery for a vehicle at a charging station, to a computer program product for carrying out such a method, and to a memory apparatus on which such a computer program product is stored.

### BACKGROUND

When a drive battery of a vehicle is being electrically charged, the vehicle must dissipate the heat arising in the process. In doing so, clearly perceptible noise may be emitted. This is notably the case with so-called fast charging processes.

Charging processes of the type in question are subject to legislative limits in terms of the noise level generated by the charging process, which generally relate to the vehicle per se. To take this into account, it is provided according to the German patent applications DE 10 2018 209 072 A1 and DE 10 2018 209 071 A1 that the vehicle derives acoustic limits as a function of the location and time of the charging process and adheres to these to as great an extent as possible. In this connection, the German patent application DE 10 2017 107 538 A1 describes that the vehicle, for this purpose, can obtain noise emission and/or noise immission limit value data from a charging station for charging the vehicle. In practical experience, it has been shown thus far that adhering to the required noise limit values continues to represent a complex challenge. The reason is that, in addition to adhering to statutory emission and immission limits, it is also important to render the charging process as energy-efficient as possible.

### SUMMARY

Aspects of the present disclosure are directed to taking the above-described problems at least partially into account. Other aspects of the present disclosure are to provide a system for energy-efficiently and/or rapidly charging a drive battery for a vehicle, by means of which it is also possible to reliably adhere to acoustic limit values.

Some aspects of the present disclosure are disclosed in the patent claims provided below. Further aspects of the present disclosure will be apparent from the dependent claims, the description and the figures. It goes without saying that features are described in connection with the method also apply in connection with the computer program product according to the present disclosure, and the memory apparatus according to the present disclosure, and vice versa, so that mutual reference is made and/or can be made in each case to the individual aspects of the invention with respect to the disclosure.

In some examples, a method is disclosed for electrically charging a drive battery for a vehicle at a charging station, wherein the vehicle comprises a refrigerant compressor for cooling the drive battery by way of refrigerant and a fan for cooling the refrigerant. The method may include the following steps:
cooling the drive battery by way of the refrigerant compressor during the electric charging of the drive battery; and
cooling the refrigerant by way of the fan during the electric charging of the drive battery, wherein an upper charging loudness limit value is provided, and the mode of operation of the refrigerant compressor as well as the mode of operation of the fan are adjusted taking the upper charging loudness limit value into consideration.

In some examples, a computer program product is disclosed, which encompasses instructions and/or commands that, when the computer program product is being executed by a computer, prompt the computer to carry out the method described above in detail. The computer program product according to the present disclosure thus entails the same advantages as those that were described in detail with respect to the method according to the present disclosure. The computer program product can be implemented in the form of tangibly-embodied computer-readable instruction code in any suitable programming language and/or computer language, such as JAVA, C++, C # and/or Python.

The computer program product can be stored on a computer-readable memory medium such as a data disk, a removable drive, a volatile or non-volatile memory, or an integrated memory/processor. The instruction code can program the computer or other programmable devices, such as a control unit, in such a way that the desired functions are carried out. Furthermore, the computer program product can be provided in a network, such as the Internet, from where it can be downloaded by a user as needed. The computer program product can be implemented both by means of software and by means of one or more special electronic circuits, that is, as hardware or in any hybrid form, that is, by means of software components and hardware components.

In addition, a memory apparatus (or memory means) is disclosed, on which a computer program product may be stored. The memory apparatus is preferably configured in the form of a computer-readable and/or non-volatile memory means. In addition, operating point-dependent activation signals, which are calculated and/or measured in advance, for executing the computer program product and/or for carrying out the method can be stored in the memory apparatus.

Further aspects will be apparent from the following description of different exemplary embodiments, which are schematically illustrated in the figures. All of the features and/or advantages that can be derived from the claims, the description or the figures, including design details and spatial arrangements, can be relevant to the invention, both alone and in the various combinations.

### DESCRIPTION OF THE DRAWINGS

In the schematic drawings:

FIG. 1 illustrates a vehicle at a charging station for electrically charging a drive battery of the vehicle, according to some aspects of the present disclosure;

FIG. 2 illustrates a memory apparatus including a computer program product stored thereon, according to some aspects of the present disclosure;

FIG. 3 illustrates a flow chart to describe a method under an embodiment, according to some aspects of the present disclosure; and

FIGS. 4 to 7 illustrate diagrams for mutually dependent operating parameters, according to some aspects of the present disclosure.

### DETAILED DESCRIPTION

Elements having identical functions and mechanisms of action are in each case denoted by identical reference numerals in the figures.

As disclosed herein, the electric charging process can be rapidly implemented as a function of an ambient sound level to be adhered to when a mode of operation of the refrigerant compressor as well as the mode of operation of the fan are taken into consideration at the same time. With this, it can be achieved, for example, that as high a refrigeration capacity as possible for battery cooling and, at the same time, as high a charging current as possible are available when a particular outside sound level and/or a sound level caused by the charging process are present.

In some examples, a cooling process can be carried out by way of at least one refrigerant compressor. The cooling of the refrigerant or a corresponding ventilation by the fan can be carried out by way of at least one fan. The refrigerant may be cooled using a heat exchanger. The upper charging loudness limit value should be understood to mean an upper charging loudness limit value for the charging station, for the vehicle and/or for a charging park. This means that the upper charging loudness limit value corresponds to a maximum permissible charging loudness, in particular in the area of the drive battery, in the area of the vehicle and/or in the area of the charging park while the drive battery is being charged. This takes aspects into consideration that remain without consideration during an examination that is separate from the vehicle. Thus, some aspects of the present disclosure relate to a charging method in which activation signals and/or operating points for different noise-inducing components, in particular for the refrigerant compressor and/or the fan, are determined and/or adjusted as a function of a predefined maximum outside sound level to be emitted. The cooling by means of refrigerant can be carried out in a variety of ways. The cooling of the drive battery by way of refrigerant may be understood to mean a cooling of the drive battery using the refrigerant compressor as well as the refrigerant.

To explain the complex interrelationships that should be considered under the present disclosure, two different cooling processes are described, and more particularly pure battery cooling and battery and passenger compartment cooling. During pure battery cooling, the suction pressure is comparatively high. The refrigerant compressor delivers a high refrigerant mass flow at a predefined rotational speed, that is, a high amount of heat to be dissipated at the condenser of the vehicle. Accordingly, a low compressor speed of the refrigerant compressor suffices when the speed of the fan is high. If a passenger compartment cooling system is activated, the suction density decreases, and so does the refrigerant mass flow. With this, excessively high heat dissipation is present for the required refrigerant mass flow. On the assumption that the charging loudness essentially remains the same, it may be useful to decrease the rotational speed of the fan, and to increase the rotational speed of the refrigerant compressor. In this way, the refrigeration capacity can be increased, with the acoustics remaining the same or with the charging loudness essentially remaining the same.

In some examples, a communication protocol may be executed and/or used between the charging station and the vehicle and/or the drive battery for carrying out charging processes. The communication protocol can be based on ISO 15118-20, for example, and be configured to enable the method steps described herein. In the present example, a communication protocol may in particular be understood to mean an agreement according to which data is transferred between the vehicle and the charging station and/or between multiple vehicles and multiple charging stations of a charging park. The communication protocol can therefore be defined as a set of rules determining the syntax, semantics and/or synchronization of the communication between the vehicle and the charging station. The communication protocol may be implemented by hardware, software, or a combination of the two. The communication protocol can in particular define the behavior of data connection hardware between the vehicle and the charging station.

A data transfer between the vehicle and the charging station for carrying out the method according to the present disclosure may be carried out via a charging cable for electrically charging the drive battery. Nonetheless, it is possible that, alternatively and/or additionally, a wireless data transfer is carried out between the vehicle and the charging station, for example for executing the communication protocol. For this purpose, the vehicle, the charging station and/or a charging park including the charging station may include corresponding receivers/transmitters.

The vehicle may be understood to mean an all-electric vehicle comprising an electric motor, or a hybrid electric vehicle comprising an electric motor and a combustion engine. The drive battery shall in particular be understood to mean the high-voltage battery of the vehicle for driving the vehicle. The method according to the present disclosure is preferably carried out to electrically charge the drive battery in a vehicle. Nonetheless, it is possible for the drive battery to be charged outside a vehicle within the scope of the method.

The upper charging loudness limit value being provided may be understood to mean that the particular value is provided for processing in a suitable controller. The controller may be provided in the vehicle, in the charging station, or as an external component outside the vehicle and outside the charging station, for example as a central controller of a charging park including multiple charging stations. Charging the drive battery taking the upper charging loudness limit value into consideration may be understood to the effect that the electric charging of the drive battery is controlled taking the upper charging loudness limit value into consideration. The drive battery is preferably charged in a direct current mode. The upper charging loudness limit value may be understood to mean a standardized limit value, and in particular a standardized sound pressure limit value. Furthermore, the charging loudness limit value may be understood to mean an acoustic power limit value and/or a loudness fluctuation intensity limit value.

In addition, or as an alternative to the charging loudness limit value, psychoacoustic limit values, such as an acoustic sharpness and/or roughness limit value, can be analogously taken into consideration. It may therefore be preferred when, in the case of local measurements, all vehicles and/or charging drive batteries, to as great an extent as possible, are measured according to the same and/or a standardized measurement method. Within the scope of the standardized measurement method, the loudness emanating from the vehicle and/or from the drive battery can be measured, for example, at a predefined distance with respect to the vehicle and/or the drive battery of, for example, one meter and/or at a predefined distance with respect to the ground of, for example, likewise one meter by way of a microphone, in particular by way of a standardized microphone.

The upper charging loudness limit value can be provided as a time-dependent upper charging loudness limit value. Viewed over the day and the night, the limit value can thus be provided with different values. For example, a higher limit value may be provided during the day than during the night. If, for example, the ambient conditions and/or the point of time of the electric charging process change, the upper charging loudness limit value can also change. This can have corresponding effects on the charging process or a control process for controlling the electric charging process.

Adjusting a mode of operation may be understood to mean to adjust an operating point. For example, adjusting the mode of operation may be understood to mean adjusting and/or accordingly activating components of the refrigerant compressor and/or of the fan, which are responsible for the corresponding operation and/or the corresponding mode of operation of the particular components.

In some examples, the mode of operation of the refrigerant compressor may be adjusted as a function of the mode of operation of the fan and/or the mode of operation of the fan is adjusted as a function of the mode of operation of the refrigerant compressor. This means that the mode of operation of the refrigerant compressor and the mode of operation of the fan are not considered separately from one another, but in mutual relation to one another. For example, the mode of operation of the refrigerant compressor can be adjusted as a function of the upper charging loudness limit value and, at the same time, as a function of the mode of operation of the fan. The mode of operation of the fan can be adjusted as a function of the upper charging loudness limit value and, at the same time, as a function of the mode of operation of the refrigerant compressor. With this, it is possible to effectively achieve the desired goal of a charging process that is as fast as possible, while taking the ambient noise into consideration.

In some examples, the mode of operation of the refrigerant compressor may be adjusted via a rotational speed of the refrigerant compressor and/or the mode of operation of the fan is adjusted via a rotational speed of the fan. The mode of operation of the refrigerant compressor and/or the mode of operation of the fan being adjusted via the respective rotational speed may be understood to mean that the rotational speed of the refrigerant compressor and/or the rotational speed of the fan are adjusted, taking the upper charging loudness limit value into consideration, so as to thereby set the corresponding operating state of the refrigerant compressor and/or of the fan. In other words, a mode of operation of the refrigerant compressor, having a certain rotational speed of the refrigerant compressor or of a shaft of the refrigerant compressor, is selected as a function of the upper charging loudness limit value. By adjusting the respective rotational speed, it is possible to easily and effectively influence the desired charging loudness limit value, while adhering to as optimal a refrigeration capacity as possible.

In some examples, a refrigerant pressure upstream from the refrigerant compressor and/or downstream from the refrigerant compressor may be determined, wherein the mode of operation of the refrigerant compressor and/or the mode of operation of the fan are adjusted as a function of the ascertained refrigerant pressure upstream from the refrigerant compressor and/or as a function of the ascertained refrigerant pressure downstream from the refrigerant compressor. This also allows the desired charging loudness limit value to be adhered to, with as a high a refrigeration capacity as possible. In particular, the sound level of the compressor can be influenced, with the rotational speed of the refrigerant compressor remaining constant. The refrigerant pressure to be taken into consideration is preferably ascertained directly upstream from the refrigerant compressor, in particular in an entrance region of the refrigerant compressor and/or directly downstream from the refrigerant compressor, in particular in an exit region of the refrigerant compressor.

In some examples, an outside temperature in the surrounding area of the vehicle may be determined, wherein the mode of operation of the refrigerant compressor and/or the mode of operation of the fan are adjusted as a function of the ascertained outside temperature. This also allows the desired charging loudness limit value to be adhered to, with as a high a refrigeration capacity as possible. The outside temperature can be determined via a temperature measuring unit directly at the vehicle and/or directly at the charging station, or remotely, away from the vehicle and/or the charging station, and be provided for carrying out the method.

So as to achieve the desired charging loudness limit value with as high a refrigeration capacity as possible, a suction pressure may be determined at the refrigerant compressor, wherein the mode of operation of the refrigerant compressor and/or the mode of operation of the fan are adjusted as a function of the determined suction pressure.

In some examples, a temperature of the drive battery and/or a temperature at the driver battery may be determined, wherein the mode of operation of the refrigerant compressor and/or the mode of operation of the fan are adjusted as a function of the ascertained temperature or taking the ascertained temperature into consideration.

In some examples, the vehicle can also include a heat exchanger for a defined heat transport between the coolant and the refrigerant, wherein a temperature of the heat exchanger or a temperature at the heat exchanger is ascertained, wherein the mode of operation of the refrigerant compressor and/or the mode of operation of the fan are adjusted as a function of the ascertained temperature of the heat exchanger and/or at the heat exchanger. Analogously, it is possible for a refrigerant temperature of a refrigerant to be ascertained for the heat exchanger, wherein the mode of operation of the refrigerant compressor and/or the mode of operation of the fan are adjusted as a function of the ascertained refrigerant temperature.

In some examples, the vehicle may include an adjustable blocking unit for controlling the cooling air aerodynamics and for determining an adjustment position of the blocking unit, wherein the mode of operation of the refrigerant compressor and/or the mode of operation of the fan are adjusted as a function of the determined adjustment position of the blocking unit for reaching the desired charging loudness limit value, at as a high a refrigeration capacity as possible. A blocking unit may be understood to mean a radiator shutter or a radiator blind having an adjustable opening degree and/or an active grill shutter. Active grills of a radiator shutter have thus far been used to reduce the fuel consumption by being closed automatically when the combustion engine requires little cooling air. Within the scope of the present invention, it was recognized that the radiator shutter and/or a blocking unit can also be used to achieve the aforementioned objects. Even though the refrigeration capacity declines with reduced air volume, this may nonetheless be of advantage or interest at a low charging loudness limit value with respect to a driving direction. According to the invention, the radiator shutter can accordingly be used to reduce the emission of the sound of the refrigerant compressor and/or of the fan in at least one direction.

In some examples, the upper charging loudness limit value may be provided with respect to at least one predefined cardinal emission direction from the vehicle into the surrounding area of the vehicle. It has been shown that taking the cardinal direction or cardinal directions into consideration can have a surprisingly large effect on the procedure for the desired charging of the drive battery, while adhering to all requirements to as great an extent as possible. When charging the drive battery, it is therefore not only possible to consider and/or require that the upper charging loudness limit value is 65 dB, for example, but also that the upper charging loudness limit value with respect to the vehicle, the charging station and/or a charging park including multiple charging stations is 60 dB toward the north and 70 dB in the other cardinal directions. In this way, the charging process can, for example, be carried out as a function of the design of a charging park including multiple charging stations and/or the charging stations themselves, the orientation of a charging station in a certain cardinal direction, the orientation of the vehicle in certain cardinal directions, the orientation and/or position of the vehicle in relation to the charging station and/or the orientation and/or position of the vehicle in the charging park.

For the determination of the charging rate and the charging loudness associated therewith, it may thus make a difference, for example, whether the vehicle is situated transversely or longitudinally with respect to the charging station, or whether the vehicle is parked at a charging station of a charging park close to a residential area, or at a charging station of a charging park located further away from the residential area, possibly even behind a noise abatement wall. Compared to a case in which the cardinal direction and/or a specific position of the vehicle at the charging station and/or in a charging park including multiple charging stations are not taken into consideration, it is possible to use or tolerate higher charging loudness limit values. Ultimately, this has advantageous effects on the method in that the drive battery can be charged at a higher charging rate while adhering to the upper charging loudness limit value, or while developing a louder charging sound. It may furthermore be advantageous when an upper emission limit value with respect to the surrounding area of the vehicle is provided, and the mode of operation of the refrigerant compressor as well as the mode of operation of the fan are adjusted taking the upper emission limit value into consideration. So as to achieve the desired charging loudness limit value, with a refrigeration capacity being as high as possible, it may furthermore be advantageous, when the vehicle approaches the charging station, to provide a driver with a notice to park and/or to orient the vehicle at the charging station and/or to display this notice in the vehicle. This can be implemented, for example, by means of a Car2x system.

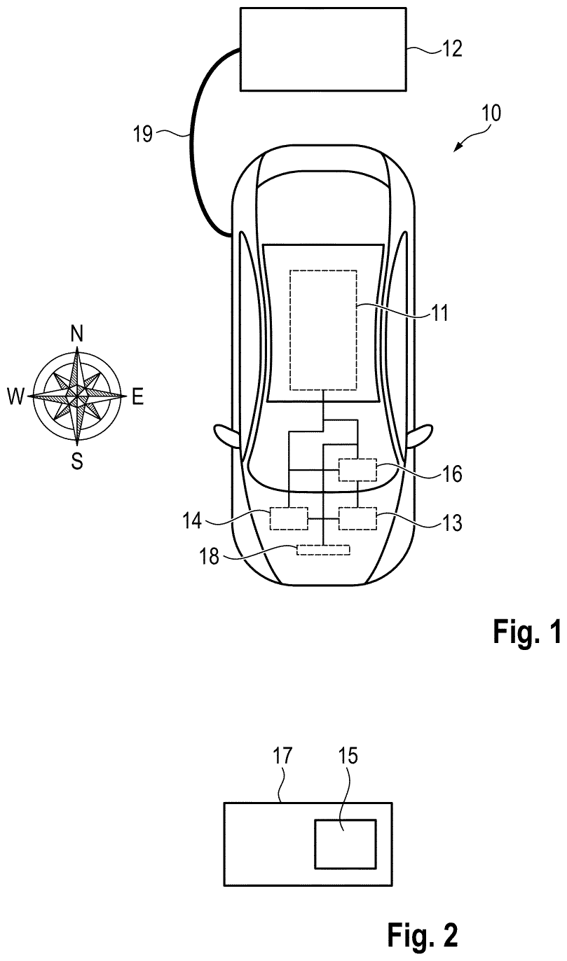

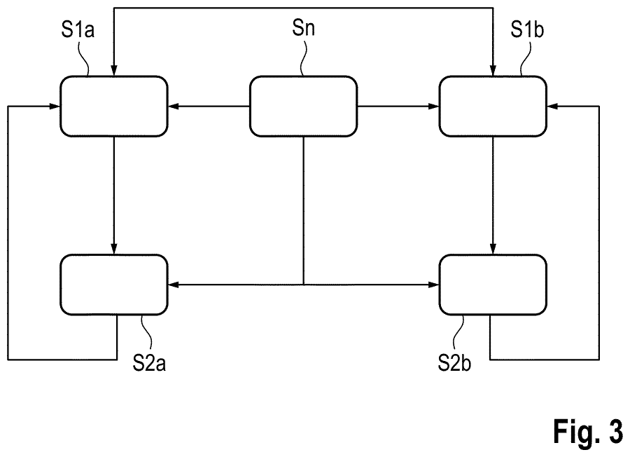

FIG. 1 shows a vehicle 10 comprising a drive battery 11, wherein the vehicle 10 is connected by a charging cable 19 to the charging station 12 for electrically charging the drive battery 11. The vehicle 10 comprises a refrigerant compressor 13 for cooling the drive battery 11 by way of refrigerant and a fan 14 for cooling the refrigerant. The vehicle 10 moreover comprises a computer 16 in the form of a vehicle control unit as well as an adjustable blocking unit 18 in the form of a radiator shutter. FIG. 2 shows a non-volatile memory apparatus 17 on which a computer program product 15 is stored. The computer program product 15 encompasses commands that, when the computer program product 15 is being executed by a computer 16, such as that of the vehicle 10, prompt this computer to carry out a method for electrically charging a drive battery 11 for a vehicle 10 at a charging station 12.

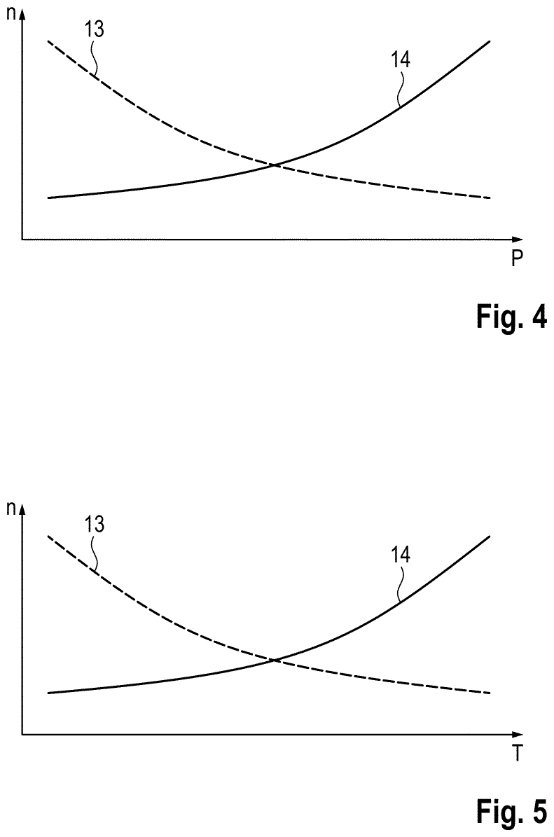

Such a method will now be described in detail with reference to FIG. 3 and FIG. 1. In a step S1a, the drive battery 11 is cooled, during the electric charging of the drive battery 11, by way of the refrigerant compressor 13. In a parallel step S1b, the refrigerant is cooled by means of the fan 14. At the same time, an upper charging loudness limit value is provided in a step Sn. This value is preferably read out from a memory and/or produced locally as a function of further ambient conditions. The mode of operation of the refrigerant compressor 13 is now adjusted as a function of the mode of operation of the fan 14 and taking the upper charging loudness limit value into consideration. The refrigerant compressor 13 is subsequently operated according to step S2a. Moreover, in particular simultaneously or at least partially simultaneously, the mode of operation of the fan 14 is adjusted as a function of the mode of operation of the refrigerant compressor 13 and taking the upper charging loudness limit value into consideration. The fan 14 is subsequently operated according to step S2b. The refrigerant compressor 13 and the fan 14 can now be continuously adjusted as a function of one another and as a function of the upper charging loudness limit value.

To adjust the desired mode of operation of the refrigerant compressor 13, the rotational speed of the refrigerant compressor 13 is set to a certain value. To adjust the desired mode of operation of the fan 14, the rotational speed of the fan 14 is set to a certain value.

In addition to the shown embodiments, the present disclosure contemplates further design variations. As a result, the present disclosure should not be considered to be limited to the exemplary embodiments described with reference to the figures.

In step Sn, for example, additionally an outside temperature in the surrounding area of the vehicle 10 can be ascertained, wherein the mode of operation of the refrigerant compressor 13 and/or the mode of operation of the fan 14 are adjusted as a function of the ascertained outside temperature. Within the scope of step Sn, moreover a refrigerant pressure upstream from the refrigerant compressor 13 and/or downstream from the refrigerant compressor 13 can be ascertained, wherein the mode of operation of the refrigerant compressor 13 and/or the mode of operation of the fan 14 are adjusted as a function of the ascertained refrigerant pressure upstream from the refrigerant compressor 13 and/or as a function of the ascertained refrigerant pressure downstream from the refrigerant compressor 13.

Additionally, in step Sn, a suction pressure at the refrigerant compressor 13 can be ascertained, wherein the mode of operation of the refrigerant compressor 13 and/or the mode of operation of the fan 14 are adjusted as a function of the ascertained suction pressure. In addition, in step Sn, a temperature of the drive battery 11 and/or at the drive battery 11 can be ascertained, wherein the mode of operation of the refrigerant compressor 13 and/or the mode of operation of the fan 14 are adjusted as a function of this ascertained temperature. Furthermore, the vehicle 10 can comprise a heat exchanger for a defined heat transport between the coolant and the refrigerant, wherein in step Sn a temperature of the heat exchanger or a temperature at the heat exchanger is ascertained, and wherein the mode of operation of the refrigerant compressor 13 and/or the mode of operation of the fan 14 are adjusted as a function of this ascertained temperature. Moreover, in step Sn, a refrigerant temperature of a refrigerant for the heat exchanger can be ascertained, wherein the mode of operation of the refrigerant compressor 13 and/or the mode of operation of the fan 14 are adjusted as a function of the ascertained refrigerant temperature.

In addition, in step Sn, an adjustment position of the blocking unit 18 can be ascertained, wherein the mode of operation of the refrigerant compressor 13 and/or the mode of operation of the fan 14 are adjusted as a function of the ascertained adjustment position of the blocking unit 18. The upper charging loudness limit value can be provided with respect to at least one predefined emission cardinal direction from the vehicle 10 into the surrounding area of the vehicle 10.

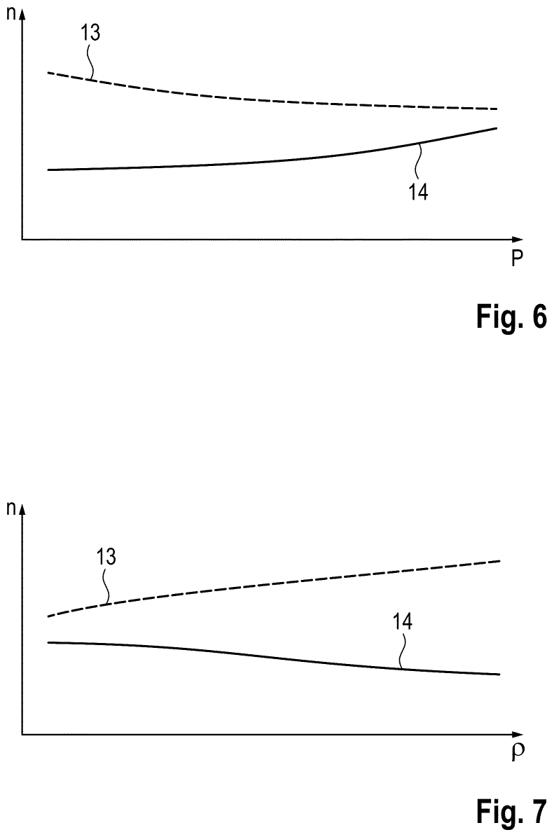

Different relationships between operating parameters for adjusting different modes of operation and/or operating points of the refrigerant compressor 13 as well as of the fan 14 will now be described with reference to the diagrams of FIGS. 4 to 7, which can be taken into consideration when adjusting the modes of operation of the refrigerant compressor 13 and/or of the fan 14. In FIG. 4, the rotational speed is plotted against the suction pressure. The dotted line denotes the refrigerant compressor 13, and the solid line denotes the fan 14. Looking at FIG. 4, it is apparent that the rotational speed of the refrigerant compressor 13 decreases with increasing suction pressure. Looking at the fan 14, the rotational speed increases with increasing suction pressure.

In FIG. 5, the rotational speed is plotted against the outside temperature. Looking at FIG. 5, it is apparent that the rotational speed of the refrigerant compressor 13 decreases as the outside temperature increases. Looking at the fan 14, the rotational speed increases as the outside temperature increases.

In FIG. 6, the rotational speed is plotted against the high pressure. Looking at FIG. 6, it is apparent that the rotational speed of the refrigerant compressor 13 decreases slightly with increasing high pressure. Looking at the fan 14, the rotational speed increases slightly with increasing high pressure.

In FIG. 7, the rotational speed is plotted against the opening degree of the blocking unit 18. Looking at FIG. 7, it is apparent that the rotational speed of the refrigerant compressor 13 decreases slightly as the opening degree increases. Looking at the fan 14, the rotational speed decreases slightly as the opening degree increases.

### LIST OF REFERENCE NUMERALS

10 vehicle
11 drive battery
12 charging station
13 refrigerant compressor
14 fan
15 computer program product
16 computer
17 memory means
18 blocking unit
19 charging cable

1-13. (canceled)

14. A method for electrically charging a drive battery for a vehicle at a charging station, the vehicle comprising a refrigerant compressor for cooling the drive battery by way of a refrigerant and a fan for cooling the refrigerant, the method comprising:
cooling a drive battery via a refrigerant compressor during charging of the drive battery; and
cooling the refrigerant via the fan during the charging of the drive battery;
receiving an upper charging loudness limit value;
adjusting a mode of operation of the refrigerant compressor; and
adjusting a mode of operation of the fan based on the received upper charging loudness limit value.

15. The method according to claim 14, wherein adjusting the mode of operation of the refrigerant compressor comprises (i) adjusting the mode of operation as a function of the mode of operation of the fan and/or (ii) adjusting the mode of operation of the fan as a function of the mode of operation of the refrigerant compressor.

16. The method according to claim 14, wherein adjusting the mode of operation of the refrigerant compressor comprises (i) adjusting the mode of operation via a rotational speed of the refrigerant compressor and/or (i) adjusting the mode of operation of the fan via a rotational speed of the fan.

17. The method according to claim 14, further comprising:
determining a refrigerant pressure upstream from the refrigerant compressor and/or downstream from the refrigerant compressor; and
adjusting the mode of operation of the refrigerant compressor and/or the mode of operation of the fan as a function of the ascertained refrigerant pressure upstream from the refrigerant compressor and/or as a function of the determined refrigerant pressure downstream from the refrigerant compressor.

18. The method according claim 14, further comprising determining an outside temperature in a surrounding area of the vehicle, and adjusting the mode of operation of the refrigerant compressor and/or the fan as a function of the ascertained outside temperature.

19. The method according to claim 14, further comprising determining a suction pressure at the refrigerant compressor, and adjusting the mode of operation of the refrigerant compressor and/or the mode of operation of the fan as a function of the determined suction pressure.

20. The method according to claim 14, further comprising determining a temperature of the drive battery and/or at the drive battery, and adjusting the mode of operation of the refrigerant compressor and/or the mode of operation of the fan as a function of the determined temperature.

21. The method according to claim 14, further comprising determining a temperature of or at a heat exchanger, and adjusting the mode of operation of the refrigerant compressor and/or the fan as a function of the ascertained temperature.

22. The method according to claim 14, further comprising determining a refrigerant temperature of a refrigerant for a heat exchanger, and adjusting the mode of operation of the refrigerant compressor and/or the fan as a function of the determined refrigerant temperature.

23. The method according to claim 14, further comprising
determining an adjustment position of an adjustable blocking unit configured to control cooling air aerodynamics; and
adjusting the mode of operation of the refrigerant compressor and/or the fan as a function of the determined adjustment position of the blocking unit

24. The method according to claim 14, wherein the upper charging loudness limit value is received with respect to at least one predefined emission cardinal direction from the vehicle into the surrounding area of the vehicle.

25. A system for electrically charging a drive battery for a vehicle at a charging station, comprising:
a refrigerant compressor for cooling the drive battery by way of a refrigerant and a fan for cooling a refrigerant;
a processing apparatus, operatively coupled to the refrigerant compressor; and
a memory, operatively coupled to the processing apparatus, wherein the processing apparatus and memory are configured to
cool a drive battery via a refrigerant compressor during charging of the drive battery; and
cool the refrigerant via the fan during the charging of the drive battery;
receive an upper charging loudness limit value;
adjust a mode of operation of the refrigerant compressor; and
adjust a mode of operation of the fan based on the received upper charging loudness limit value.

26. The system according to claim 25, wherein the processing apparatus and memory are configured to adjust the mode of operation of the refrigerant compressor by (i) adjusting the mode of operation as a function of the mode of operation of the fan and/or (ii) adjusting the mode of operation of the fan as a function of the mode of operation of the refrigerant compressor.

27. The system according to claim 25, wherein the processing apparatus and memory are configured to adjust the mode of operation of the refrigerant compressor by (i) adjusting the mode of operation via a rotational speed of the refrigerant compressor and/or (i) adjusting the mode of operation of the fan via a rotational speed of the fan.

28. The system according to claim 25, wherein the processing apparatus and memory are configured to:
determine a refrigerant pressure upstream from the refrigerant compressor and/or downstream from the refrigerant compressor; and
adjust the mode of operation of the refrigerant compressor and/or the mode of operation of the fan as a function of the ascertained refrigerant pressure upstream from the refrigerant compressor and/or as a function of the determined refrigerant pressure downstream from the refrigerant compressor.

29. The system according claim 25, wherein the processing apparatus and memory are configured to determine an outside temperature in a surrounding area of the vehicle, and adjust the mode of operation of the refrigerant compressor and/or the fan as a function of the ascertained outside temperature.

30. The system according to claim 25, wherein the processing apparatus and memory are configured to determine a suction pressure at the refrigerant compressor, and adjust the mode of operation of the refrigerant compressor and/or the mode of operation of the fan as a function of the determined suction pressure.

31. The system according to claim 25, wherein the processing apparatus and memory are configured to determine a temperature of the drive battery and/or at the drive battery, and adjust the mode of operation of the refrigerant compressor and/or the mode of operation of the fan as a function of the determined temperature.

32. The system according to claim 25, wherein the processing apparatus and memory are configured to:
determine a refrigerant pressure upstream from the refrigerant compressor and/or downstream from the refrigerant compressor; and
adjust the mode of operation of the refrigerant compressor and/or the mode of operation of the fan as a function of the ascertained refrigerant pressure upstream from the refrigerant compressor and/or as a function of the determined refrigerant pressure downstream from the refrigerant compressor.

33. A non-transitory computer-readable medium having stored therein instructions executable by one or more processors for electrically charging a drive battery for a vehicle at a charging station, the vehicle comprising a refrigerant compressor for cooling the drive battery by way of a refrigerant and a fan for cooling the refrigerant, the instructions being configured to:
cool a drive battery via a refrigerant compressor during charging of the drive battery; and
cool the refrigerant via the fan during the charging of the drive battery;
receive an upper charging loudness limit value;
adjust a mode of operation of the refrigerant compressor; and
adjust a mode of operation of the fan based on the received upper charging loudness limit value.
